(19) United States
(12) Patent Application Publication
(10) Pub. No.: US 2014/0239949 A1
(43) Pub. Date: Aug. 28, 2014

(54) MR IMAGING USING SHARED INFORMATION AMONG IMAGES WITH DIFFERENT CONTRAST

(71) Applicant: KONINKLIJKE PHILIPS N.V., EINDHOVEN (NL)

(72) Inventors: Feng Huang, Gainesville, FL (US); George Randall Duensing, Gainesville, FL (US); Wei Lin, Gainesville, FL (US)

(73) Assignee: KONINKLIJKE PHILIPS N.V. a corporation

(21) Appl. No.: 14/352,599

(22) PCT Filed: Oct. 10, 2012
(86) PCT No.: PCT/IB2012/055471

§ 371 Date: Apr. 17, 2014

Related U.S. Application Data
(60) Provisional application No. 61/548,241, filed on Oct. 18, 2011.

(51) Int. Cl. G01R 33/56

(52) U.S. Cl. CPC G01R 33/56
USPC 324/307; 324/319

(57) ABSTRACT

A method of magnetic resonance imaging includes performing a first magnetic resonance scan sequence which saves a data store, and performing a second magnetic resonance scan sequence which uses a data store from the first magnetic resonance scan sequence. A magnet (10) generates a B₀ field in an examination region (12), a gradient coil system (14, 22) creates magnetic gradients in the examination region, and an RF system (16, 18, 20) induces resonance in and receives resonance signals from a subject in the examination region. One or more processors (30) are programmed to perform a magnetic resonance pre-scan sequence to generate pre-scan information, perform a first sequence to generate first sequence data, refine the pre-scan information with the first sequence data, perform a second imaging sequence to generate second sequence data. Further, the second sequence data is either reconstructed using the refined pre-scan information or performed using the refined pre-scan sequence information.

The present application relates to Magnetic Resonance (MR) arts. It finds particular application in conjunction with magnetic resonance imaging (MRI) but may also find application in magnetic resonance spectroscopy (MRS).

Magnetic Resonance Imaging (MRI) uses a pre-scan to calibrate and create initial references before each scan sequence. A typical pre-scan includes a coil survey, a sense reference, a B0 mapping, and a B1 mapping. A coil survey typically lasts more than 10 seconds. A sense reference typically lasts more than 10 seconds. A B0 mapping lasts more than 15 seconds, and a B1 mapping lasts between 15 and 30 seconds. The total pre-scan can last longer than one minute. If the coil or the patient position change, then the information is inaccurate. Ideally, all of these pre-scans need be repeated. Otherwise, the reconstructed image may contain serious artefacts. However, the repetition of these reference scans prolong the total acquisition time.

Moreover, the pre-scan is usually run at a low resolution to save time. If the coil elements are small, a low resolution image may not provide sufficiently accurate coil sensitivity maps. A lack of sufficiently accurate coil sensitivity maps result in residual aliasing artefacts in SENSE images.

A typical imaging subject is scanned with an average of 4 or more imaging sequences. The imaging sequences are typically performed on the same region of interest but focus on different aspects of the subject anatomy, achieve different contrasts, and the like. Since the same subject is scanned in the same system using the same RF coil, the information such as B0, B₁⁻, optimized acquisition trajectory and reconstruction parameters, etc, can be shared among these scans for different contrasts to improve the image quality. The present application provides a new and improved MR imaging using shared information which overcomes the above-referenced problems and others using one set of pre-scans.

In accordance with one aspect, a magnetic resonance method is provided in which a pre-scan sequence is followed by a plurality of scanning sequences without pre-scan sequences in between and in which information of the pre-scan sequence is refined by each scan sequence.

In accordance with another aspect, a magnetic resonance system includes a magnet which generates a B0 field in an examination region, a gradient coil system which creates magnetic gradients in the examination region, and an RF system which induces resonance in and receives resonance signals from a subject in the examination region. The system further includes one or more processors which are programmed to control the RF and gradient coil systems to perform a pre-scan sequence to generate pre-scan data. The pre-scan data is processed to create pre-scan information. The RF system and the gradient coil system are controlled to use the pre-scan information to perform a first sequence to generate first sequence data, as well as refined pre-scan data. The one or more processors controls at least one of the RF and gradient coil systems using the refined pre-scan data to perform a second sequence to generate second sequence data and/or reconstruction of the second sequence data into an image representation using refined pre-scan information.

In accordance with another aspect, a magnetic resonance method includes performing a magnetic resonance pre-scan sequence to generate pre-scan information, performing a first sequence to generate first sequence data, and refining the pre-scan information with the first sequence data to create refined pre-scan information. A second scan sequence is performed to generate second scan data and at least one of the second scan sequence is reconstructed using the refined pre-scan information and/or the refined pre-scan sequence information is used when performing the second scan sequence.

In accordance with another aspect, a magnetic resonance method is provided in which an RF and gradient coil system are controlled to perform a pre-scan sequence to generate pre-scan information and perform a first imaging sequence to generate first image sequence data. The first image data is reconstructed using the pre-scan information to generate a first image representation. The first imaging sequence data is used to refine the pre-scan information. The RF and gradient coil systems are controlled to perform a second imaging sequence to generate second imaging data. The second imaging sequence data are reconstructed using the refined pre-scan information to generate a second image representation.

One advantage is that total time for a subject in a scanner is reduced.

Another advantage is that pre-scans between sequences due to patient or coil motion are reduced or eliminated.

Another advantage is that the order of scans can be optimized.

Another advantage resides in correcting motion across imaging sequences.

Another advantage resides in accelerating individual sequences using a priori information.

Another advantage is that the accuracy of pre-scan information and reconstructed images are improved.

Another advantage resides in avoiding mis-registration due to motion.

Another advantage resides in replacing corrupted data with uncorrupted data.

Another advantage is that the information from prior images guides the sampling trajectory.

Another advantage is that the parameters used in reconstruction can be optimized using prior images.

Still further advantages of the present invention will be appreciated to those of ordinary skill in the art upon reading and understand the following detailed description.

The invention may take form in various components and arrangements of components, and in various steps and arrangements of steps. The drawings are only for purposes of illustrating the preferred embodiments and are not to be construed as limiting the invention.

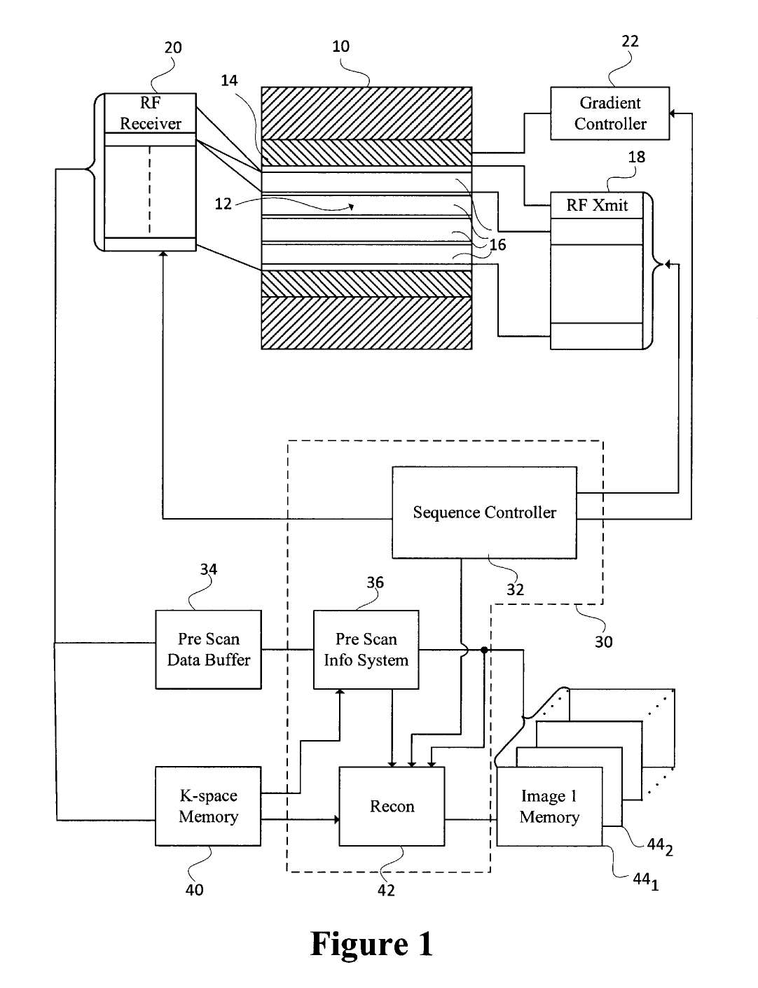

FIG. 1 is a diagrammatic illustration of a magnetic resonance imaging system in accordance with the present invention.

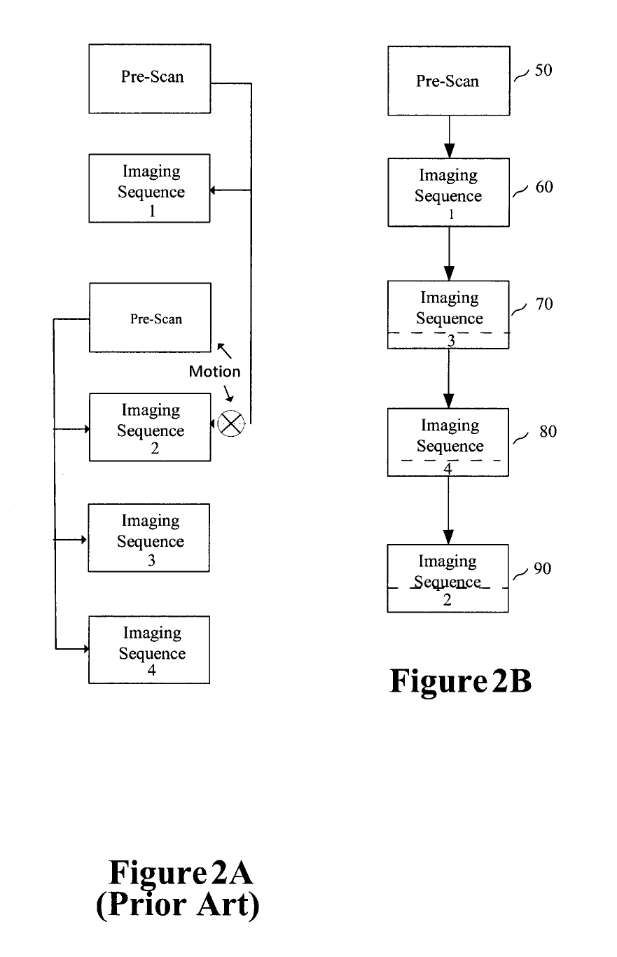

FIGS. 2A and 2B illustrate the difference between a typical subject imaging sequence (FIG. 2A) and an embodiment of the present application (FIG. 2B).

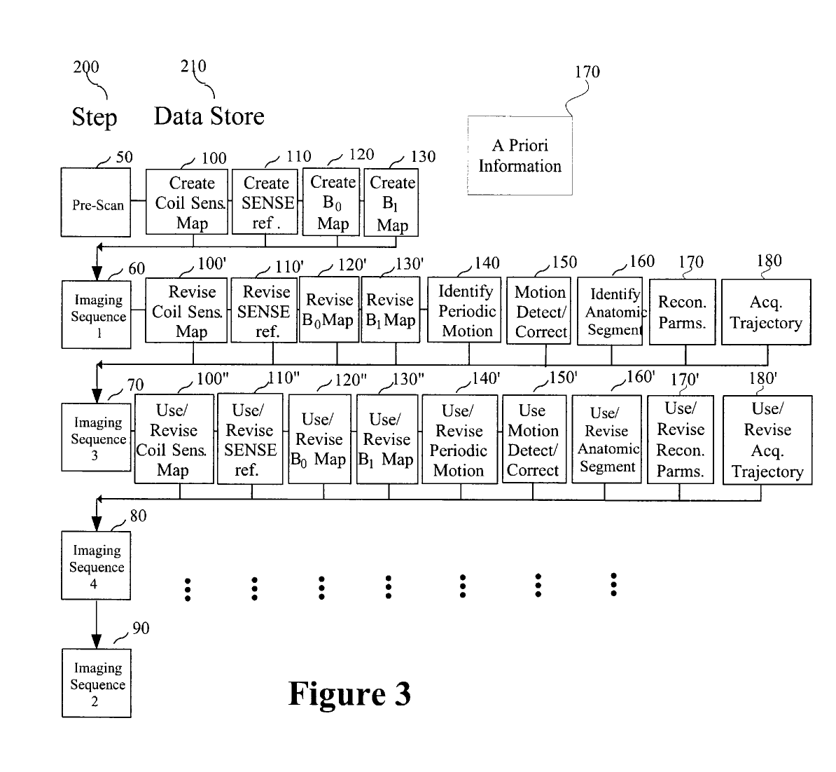

FIG. 3 illustrates sharing data stores.

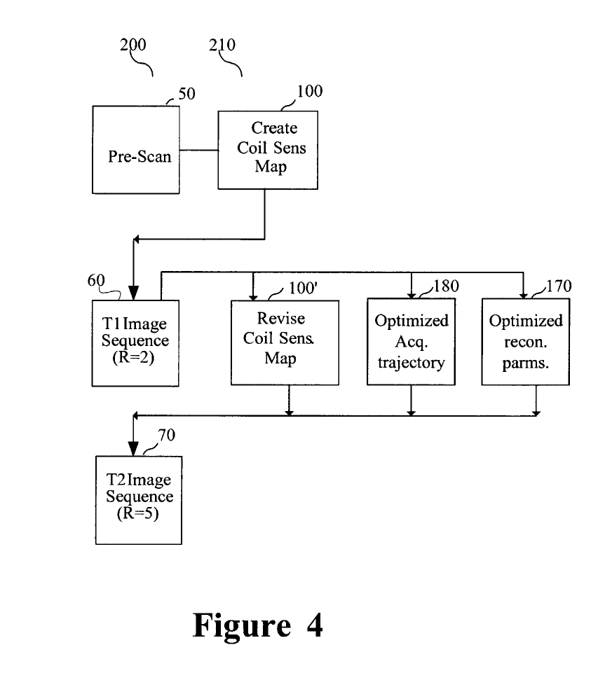

FIG. 4 illustrates imaging sequences ordered to optimize the pre-scan of information for subsequent imaging sequences.

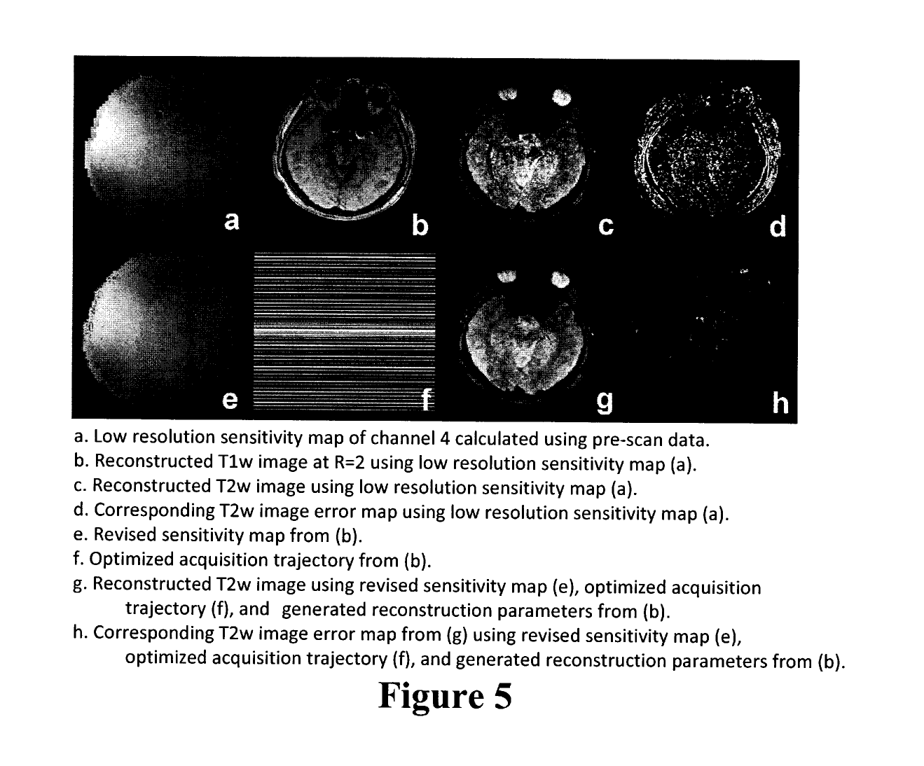

FIG. 5 illustrates images from embodiments of the process technique.

With reference to FIG. 1, a magnetic resonance imaging system includes a magnet 10 which generates a static B₀ field in an examination region 12. One or more gradient magnetic field magnets 14 generate magnetic field gradients across the B₀ field in the imaging region. Radiofrequency coils or elements 16 generate B₁ RF pulses for exciting and manipulating magnetic resonance and induce magnetic resonance signals. Although illustrated as whole body transmit and receive RF coils, it is to be appreciated that separate RF coils can be provided for transmitting and receiving and that the receive and/or the transmit coils may be local coils, whole body coils, or a combination of the two. Although illustrated as a bore type magnetic resonance system, C-type or open magnetic resonance systems are also contemplated. One or more RF transmitters 18 apply RF signals to the radiofrequency coils to cause the B₁ pulses to be applied in the examination region. One or more receivers 20 receive the magnetic and demodulate the magnetic resonance signals received by the RF coils 16. A gradient controller 22 controls the gradient coil 14 to apply the gradient magnetic field pulses across the examination region, commonly a combination of orthogonal gradients denoted as x, y, and z gradients.

One or more processors 30 include a sequence controller 32 such as a sequence control computer algorithm, a sequence control module, or the like. As explained in greater detail below, the sequence controller 32 controls the one or more RF transmitters 18, the gradient controller 22, and the one or more RF receivers 20 to conduct a pre-scan magnetic resonance sequence followed by a plurality of different magnetic resonance sequences, such as a T₁ weighted imaging sequence, a T₂ weighted imaging sequence, a diffusion weighted imaging sequence, or the like. The magnetic resonance signals from the pre-scan sequence are stored in a pre-scan data or information buffer 34. The one or more processors 30 includes the pre-scan information system 36 which derives pre-scan information from the pre-scan data, such as coil sensitivity maps, a B₀ map, a B₁ map, and the like as is explained in greater detail below.

The sequence controller 32 uses the pre-scan information to adjust the parameters of the first imaging sequence and controls the RF transmitter, RF receivers, and the gradient controller 22 to generate the first imaging sequence which is stored in a k-space data memory 40. The one or more processors 30 further include a reconstruction module, series of program instructions, ASICs or the like. The reconstruction processor 12 reconstructs the first scan data from the k-space memory 40 into a first image representation which is stored in a first image memory 44₁. The reconstruction is performed using the pre-scan information from the pre-scan information system 36. The pre-scan information system, in turn, uses the first scan data from the k-space memory 40 and data from the reconstructed image from the first image memory 44₁ to update, refine, and improve the accuracy of the pre-scan information. The sequence controller 32 uses the improved pre-scan information to conduct the second imaging scan which is reconstructed into a second image representation that is stored in a second image representation memory 44₂. The pre-scan information system 36 again updates, improves, and makes the pre-scan information more accurate. This process is repeated generating the third and subsequent images in the sequence with the pre-scan information being updated, improved, and rendered more accurate before each subsequent scan sequence. Also, k-space or image data from earlier sequences can be used by the reconstruction processor to accelerate or refine the images of later sequences.

With reference to FIG. 2A, a set of four-scan sequences is diagrammed for logical comparison with the method which is the subject of this application in FIG. 2B. Previously, each scan sequence was run independently. Each scan sequence commences by sharing one pre-scan sequence 50 unless motion happens. Most scans in one protocol included the same information for the same patient for the same session, and typically scan the same region of interest for different contrasts. In FIG. 2B, the pre-scan sequences between imaging sequences are eliminated and the imaging sequences are run consecutively following a single pre-scan sequence 50. Individual sequences may run in reduced in the amount of time, or performed with an accelerated method by sharing data from one image sequence to the next. In addition, the ordering of the sequences may be altered to reduce the overall scan time. Earlier sequences are selected that create data stores which are most efficiently used by later sequences. The order reduces the overall time of scanning while either maintaining or improving the quality of the resulting images.

FIG. 2B shows the re-ordered set of sequences which move the second imaging sequence to last. The dotted lines across the imaging sequences indicate a reduction in scan time or acceleration due to use of common information stores from the pre-scan or prior scan sequences.

With reference to FIG. 3, steps 200 and data stores 210 of an MRI embodiment are diagrammed. During a pre-scan sequence 50 pre-scan data is generated from which pre-scan information is generated. The pre-scan information includes initial Radio Frequency (RF) coil sensitivity maps 100 are created. A SENSE reference 110 may be created. Initial B₀ maps 120 and B₁ maps 130 are created. The RF coil sensitivity maps 100, SENSE reference 110, calibration signal, phantom references, B₀ 120, and/or B₁ maps 130 are information generated and used during the pre-scan sequence 50. This initial pre-scan information is used for a first imaging sequence 60. The pre-scan information storage may involve files or data structures. The accuracy depends upon the lack of motion of the subject, the resolution with which it is created, and the like. Typically the pre-scan sequence 50 is run at a low resolution. The pre-scan sequence 50 is used primarily to calibrate with the actual patient load using the selected whole body or local RF coil(s). When the first scan sequence 60 is performed, the initial pre-scan information from the pre-scan sequence 50 is updated with more accurate pre-scan information 100′, 110′, 120′, 130′. Additional pre-scan information may be generated which enhances the image quality. The additional information includes periodic motion information 140, image references 150, and/or anatomical landmarks or segments 160. Various techniques are used to improve image quality, accuracy, and contrasts.

In a sense, the first image scan sequence functions both to generate a first image representation, but also as a pre-scan for a second imaging sequence. When the next sequence ends 60, the resulting imaging data is saved as a reconstructed image and/or saved as intermediate data for later image reconstruction. When a next imaging sequence 70 is started, unlike the prior art, no pre-scan is conducted. Rather, the revised pre-scan information is used instead.

In FIG. 3, the sequences 200 are re-ordered to optimize the data stores 210 that can be used in the subsequent imaging sequence(s). Several of the data stores 210 are created in the pre-scan 100, 110, 120, 130. More are added from the first imaging sequence 140, 150, 160, 170, 180. Additional data stores include subject motion references 140, full or partial k-space data, specific time frames, automated calibration signal references, anatomic landmarks or segments references 150, and other motion detection/correction references 160. The first imaging sequence 60 also revises the data stores 100′, 110′, 120′, 130′ from the pre-scan. File structures and databases may be added for performance, searching, and/or each of use. The data stores 210 exist beyond the life of the individual imaging sequence.

As the next imaging sequence 70 begins, pre-scan information is retrieved from the data stores 100′, 110′, 120′, 130′, 140, 150, 160. Specific data loaded prior to the next imaging sequence(s) depends upon what is available and what the next scan can use. The data stores 210 available depend upon the prior sequence(s). For example, periodic motion information is available if previous sequences include the appropriate anatomical regions and techniques to measure periodic motion. If the previous scan is a limb, then periodic motion may not be available. If for example, a previous cardiac imaging sequence is performed, then the cardiac landmarks 160 have already been identified, periodic motion identified 140 and measured for reference, and the maps of pre-scan information updated 100′, 110′, 120′, 130′. These data stores 210 are then used as input to the next imaging sequence 70 data collection, or its image reconstruction. Where creating data stores 210 is performed in either a pre-scan 50 or earlier imaging sequence, later sequences either use or revise the data stores. New data stores are added when new information becomes available. When motion corrupts data collection, prior data stores are used to correct, replace, or refresh the motion corrupted data. The accuracy of image registration is measured and tracked between the different imaging sequences which avoid mis-registration. The data stores 210 are again updated 100″, 110″, 120″, 130″, 140′, 150′, 160′, 170′, 180′ using data from the second imaging sequence 70.

In one embodiment illustrated in FIG. 4, a radio frequency coil sensitivity map 100′, optimized acquisition trajectory 180, and optimized reconstruction parameter 170 from a first imaging sequence is updated to improve the accuracy for a later parallel imaging sequence. Another embodiment uses an updated B₀ map 120″ improves a geometry distortion correction for a later echo planar imaging sequence. Another embodiment updates the B₁ map 130″ to reduce excitation error or improve performance of shimming in a later imaging sequence.

In another example, the first imaging sequence 60 is a T1 weighted imaging sequence with an acceleration factor of 2. The second imaging sequence 70 is a T2 sequence with an acceleration factor of 5. The RF coil sensitivity map 100 is initially created in the pre-scan 50 and placed in a data store 210. The T1 imaging sequence 60 uses and revises the RF coil sensitivity map 100′ in the data store which is then preserved and used in the T2 imaging sequence 70. The T2 imaging sequence 70 can be run faster due to the more accurate and complete RF coil sensitivity map 100′, optimized acquisition trajectory 180, and optimized reconstruction parameter 170 created with the T1 imaging sequence 60. The T2 images are reconstructed using RF coil sensitivity map 100′.

In this example, the T1 image is used to identify the region of the k-space which is of primary interest. In the T2 and subsequent images, the sequence controller can tailor the k-space directory accordingly, e.g., to sample the region of primary interest more heavily.

With reference again to FIG. 3, the information used to improve the imaging scans need not be determined from the pre-scan sequence and the prior imaging sequences. Rather, a priori information 190 can be manually input or received from other sources. The a priori information can be from prior imaging sessions, hospital database records, manual inputs, other diagnostic equipment, and the like.

With reference to FIG. 5, shows the results of this process. Subfigure (a) shows the low resolution sensitivity map of channel 4 calculated using pre-scan data. Subfigure (b) shows the reconstruction of T1w image at R=2 using low resolution sensitivity map. Subfigures (e) and (f) show the revised sensitivity map and optimized acquisition trajectory using (b). Subfigures (c) and (d) show the reconstructed T2w image (c) and the corresponding error map (d) using low resolution sensitivity map (a). Subfigures (g) and (h) show the reconstructed T2w image (g) and the corresponding error map (h) using high resolution sensitivity map (e), optimized acquisition trajectory (f), and reconstruction parameters generated using (b).

The changes in methodology may be implemented through changes in software. The changes in software are reflected in the user interface where an operator selects the imaging sequences and then the software orders the sequences. The imaging station serves as the user interface or an alternative processor may be used.

The invention has been described with reference to the preferred embodiments. Modifications and alterations may occur to others upon reading and understanding the preceding detailed description. It is intended that the invention be constructed as including all such modifications and alterations insofar as they come within the scope of the appended claims or the equivalents thereof.

1. A magnetic resonance system comprising:
a magnet which generates a B₀ field in an examination region;
a gradient coil system, which creates magnetic gradients in the examination region;
a RF system which induces resonance in and receives resonance signals from a subject in the examination region;
one or more processors programmed to:
control the RF system and the gradient coil system to perform a pre-scan sequence in which the RF system and gradient coil system generate pre-scan data;
process the pre-scan data to create pre-scan information;
control the RF system and the gradient coil system using the pre-scan information to perform a first sequence to generate first sequence data;
use the first sequence data to refine the pre-scan information and/or add information from the first image;
control at least one of:
the RF system and the gradient coil system using the refined pre-scan data and/or added information to perform a second sequence to generate second sequence data and/or
reconstruction of the second sequence data into a second image representation using the refined pre-scan information and/or the added information.

2. The system according to claim 1 wherein the one or more processors are further programmed to:
reconstruct the first sequence data into a first image representation using the pre-scan information.

3. The system according to claim 1 wherein the one or more processors are further programmed to:
re-refine the refined pre-scan and the additional information using the second sequence data; and
control the RF system and the gradient coil system using the re-refined pre-scan information and/or added information to perform a third imaging sequence to generate third sequence data; and
reconstruct the third sequence data into a third image representation using the re-refined pre-scan information or added information.

4. The system according to claim 1 wherein the pre-scan information or added information includes at least one of:
a radio frequency coil sensitivity map,
subject periodic motion reference,
k-space data,
time frames,
automated calibration signals (ACS) reference,
subject anatomic segment reference,
subject motion detection/correction reference,
a calibration signal,
a phantom reference,
subject geometry,
acquisition trajectory,
reconstruction parameters,
a B₀ map, and
a B₁ map.

5. The system according to claim 1 wherein the RF coil system includes a parallel imaging RF coil system and wherein the pre-scan information includes a radio frequency coil sensitivity map which sensitivity map is refined with the first sequence data to generate a refined radio frequency coil sensitivity map, and wherein the at least one processor at least one of controls the reconstructing of the second sequence data using the radio frequency sensitivity map and/or controls the RF system and the gradient coil system using the refined radio frequency coil sensitivity map such that the second or subsequent sequence is a parallel imaging sequence.

6. The system according to claim 1 wherein the pre-scan information includes a B₀ map and the second or a subsequent sequence is an echo planar imaging sequence.

7. The system according to claim 1 wherein the one or more processors are further programmed to:
use a portion of the first scan data in reconstructing the second scan data, such as to replace missing or defective data or to accelerate reconstruction.

8. The system according to claim 1 wherein the pre-scan information includes at least one of a radio frequency coil sensitivity map, a B₀ map, and a B₁ map.

9. A magnetic resonance method in which a pre-scan sequence is followed by a plurality of scanning sequences without pre-scan sequences in between and in which information from the pre-scan sequence is refined by each scan sequence and used in conjunction with the subsequent scan sequences and for reconstruction of scan data therefrom.

10. The method according to claim 9 further including
controlling an RF system and a gradient coil system to perform a pre-scan sequence to generate pre-scan information;
controlling the RF system and the gradient coil system to perform a first imaging sequence to generate first image sequence data;
reconstructing the first image sequence data using the pre-scan information to generate a first image representation;
using the first imaging sequence data to refine the pre-scan information;
controlling the RF system and the gradient coil system to perform a second imaging sequence to generate second imaging sequence data; and
reconstructing the second imaging sequence data using the refined pre-scan information to generate a second image representation.

11. The method according to claim 9 further including:
performing a magnetic resonance pre-scan sequence to generate pre-scan information;
performing a first sequence to generate first sequence data;
refining the pre-scan information with the first sequence data to create refined pre-scan information;
performing a second scan sequence to generate second sequence data; and
at least one of:
reconstructing the second sequence data using the refined pre-scan information; and/or
using the refined pre-scan sequence information when performing the second scan sequence.

12. The method according to claim 9, further including:
accelerating the second image sequence based on information from the first image sequence.

13. The method according to claim 9, further including:
ordering imaging sequences based on the pre-scan and refined pre-scan information.

14. The method according to claim 9, further including:
re-ordering the imaging sequences based on available data from prior imaging sequences.

15. The method according to claim 9, wherein the pre-scan information includes an RF coil sensitivity map and further including:
refining the RF coil sensitivity map with data from the first imaging sequence;
performing a parallel imaging sequence using the refined RF coil sensitivity map.

16. The method according to claim 9, wherein the pre-scan data includes a B₀ map and further including:
refining the B₀ map with data from the first imaging sequence;
performing an echo plan imaging sequence using the refined B₀ map.

17. The method according to claim 9 wherein the pre-scan information includes one or more of:
a radio frequency coil sensitivity map,
subject periodic motion reference,
k-space data,
time frames,
automated calibration signals (ACS) reference,
subject anatomic segment reference,
subject motion detection/correction reference,
a calibration signal,
a phantom reference,
subject geometry,
acquisition trajectory,
reconstruction parameters,
a B₀ map, and
a B₁ map.

18. A non-transitory computer readable medium carrying software for controlling one or more processors to perform the method according to claim 9.

19. A magnetic resonance system comprising:
a magnet which generates a B₀ field in an examination region (12);
a gradient coil system which creates magnetic gradients in the examination region;
a RF system which induces resonance in and receives resonance signals from a subject in the examination region;
one or more processors programmed to perform the method according to claim 9.
